(19) United States
(12) Patent Application Publication
(10) Pub. No.: US 2014/0070304 A1
(43) Pub. Date: Mar. 13, 2014

(54) NONVOLATILE MEMORY DEVICE AND METHOD FOR MANUFACTURING SAME

(71) Applicant: KABUSHIKI KAISHA TOSHIBA, Tokyo (JP)

(72) Inventors: Ken KOMIYA, Mie-ken (JP); Tatsuya KATO, Mie-ken (JP); Kenta YAMADA, Mie-ken (JP); Hidenobu NAGASHIMA, Mie-ken (JP)

(73) Assignee: Kabushiki Kaisha Toshiba, Tokyo (JP)

(21) Appl. No.: 13/785,069

(22) Filed: Mar. 5, 2013

(30) Foreign Application Priority Data
Sep. 11, 2012 (JP) 2012-199939

(51) Int. Cl. H01L 29/792; H01L 29/66

(52) U.S. Cl. CPC H01L 29/792; H01L 29/66833
USPC 257/326; 438/287

(57) ABSTRACT

According to an embodiment, a nonvolatile memory device includes a memory cell string, a control gate, first and second insulating films. The memory cell string includes a semiconductor layer and a plurality of memory cells disposed on the semiconductor layer. The control gate is provided on each of the memory cells. The first insulating film covers each side surface of the memory cells, and a side surface of the control gate. The second insulating film covering an upper portion of the control gate is provided on each of two adjacent memory cells. A first air gap is disposed between the two adjacent memory cells and surround by the first insulating film and the second insulating film, and the semiconductor layer is exposed by the first gap, or thickness of an insulating film between the first gap and the semiconductor layer is thinner than the first insulating film.

### CROSS-REFERENCE TO RELATED APPLICATIONS

This application is based upon and claims the benefit of priority from Japanese Patent Application No. 2012-199939, filed on Sep. 11, 2012; the entire contents of which are incorporated herein by reference.

### FIELD

Embodiments are generally related to a nonvolatile memory device and a method for manufacturing the same.

### BACKGROUND

Nonvolatile memory devices such as NAND flash memories are widely used in consumer electrical products. To meet the requirements of capacity increase and cost reduction in such memory devices, microfabrication technology is expected to further evolve in the future.

For instance, in a structure used in NAND flash memories, an air gap (void) is provided between memory cells to reduce parasitic capacitance associated with the miniaturization of memory cells. This can increase the coupling ratio of memory cells. Thus, the interference between adjacent memory cells can be suppressed to reduce threshold variation. However, there is still room for improvement to respond to further miniaturization.

### BRIEF DESCRIPTION OF THE DRAWINGS

FIG. 1 is a schematic sectional view illustrating one example of a nonvolatile memory device according to a first embodiment;

FIG. 2 is a block diagram illustrating one example of the nonvolatile memory device according to the first embodiment;

FIGS. 3A and 3B are schematic sectional views illustrating one example of the memory cell of the nonvolatile memory device according to the first embodiment;

FIGS. 4A to 8 are schematic sectional views illustrating one example of a manufacturing process of the nonvolatile memory device according to the first embodiment;

FIGS. 9A and 9B are schematic sectional views illustrating one example of a nonvolatile memory device according to a second embodiment; and

FIGS. 10A to 13B are schematic sectional views illustrating one example of a manufacturing process of the nonvolatile memory device according to the second embodiment.

### DETAILED DESCRIPTION

According to an embodiment, a nonvolatile memory device includes a memory cell string, a control gate, a first insulating film and a second insulating film. The memory cell string includes a semiconductor layer extending in a first direction and a plurality of memory cells disposed on the semiconductor layer in the first direction. The control gate is provided on each of the plurality of memory cells and extends in a second direction crossing the first direction. The first insulating film covers each side surface crossing the first direction of the plurality of memory cells, and a side surface of the control gate. The second insulating film covering an upper portion of the control gate is provided on each of two adjacent memory cells of the plurality of memory cells. A first air gap is disposed between the two adjacent memory cells and is surround by the first insulating film and the second insulating film, and the semiconductor layer is exposed by the first gap, or thickness of an insulating film between the first gap and the semiconductor layer is thinner than the first insulating film.

Embodiments will now be described with reference to the drawings. Like portions in the drawings are labeled with like reference numerals, with the detailed description thereof omitted appropriately, and the different portions are described appropriately. Various components may be described with reference to the XYZ orthogonal coordinate system shown in the drawings.

### First Embodiment

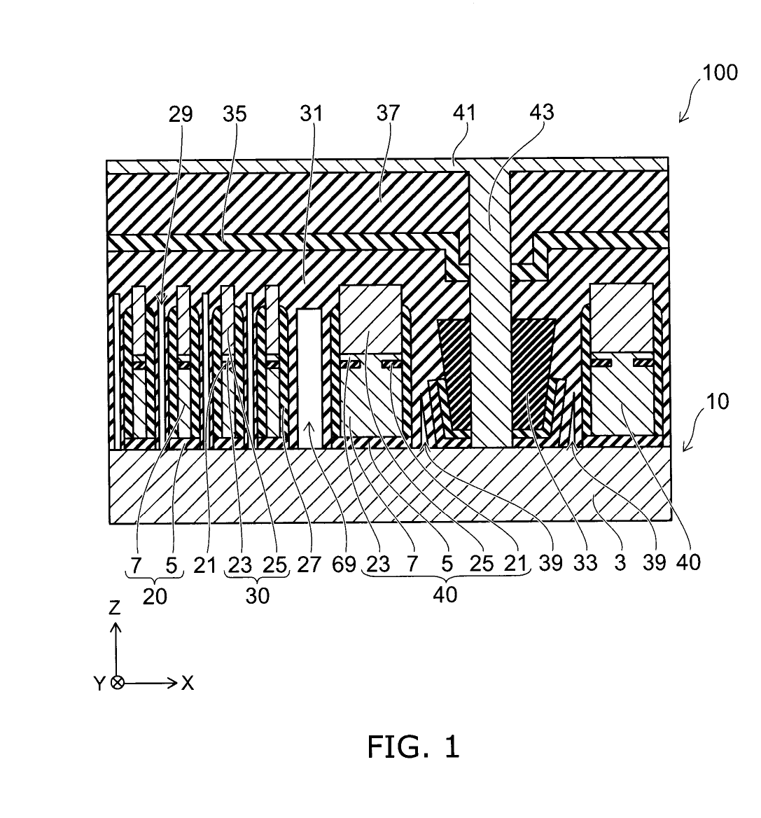

FIG. 1 is a schematic sectional view showing one example of a nonvolatile memory device 100 according to a first embodiment. The nonvolatile memory device 100 is e.g. a NAND flash memory, and includes a memory cell string 10. The memory cell string 10 includes a semiconductor layer 3 extending in a first direction (X direction), and a plurality of memory cells 20 juxtaposed on the semiconductor layer 3. The nonvolatile memory device 100 further includes a control gate 30 provided on each memory cell 20 and extending in a second direction (Y direction) crossing the first direction.

The memory cell 20 includes a tunnel insulating film 5 provided on the semiconductor layer 3, and a polycrystalline silicon (polysilicon) layer 7 functioning as a charge accumulation layer. The control gate 30 is provided on the memory cell 20 via an IPD (Inter-Poly Dielectric) film 21. The control gate 30 includes a polysilicon layer 23 and a silicide layer 25.

A select gate 40 is provided at an end of the plurality of memory cells 20. The select gate 40 includes a tunnel insulating film 5, a polysilicon layer 7, an IPD film 21, a polysilicon layer 23, and a silicide layer 25. In the select gate 40, an opening is provided in the IPD film 21. Thus, the polysilicon layer 7 and the polysilicon layer 23 are electrically connected. Accordingly, a select transistor with the tunnel insulating film 5 serving as a gate insulating film is configured at the intersection of the semiconductor layer 3 and the select gate 40. The select transistor controls the current flowing in the memory cell 20 via the semiconductor layer 3.

An insulating film 27 (first insulating film) is provided on the side surface crossing the X direction of the memory cell 20. The insulating film 27 covers the side surface of the memory cell 20 and the side surface of the control gate 30 to protect the memory cell 20. An insulating film 31 (second insulating film) is provided on the plurality of memory cells 20. The insulating film 31 covers the upper portion of the control gate 30 provided on each of two adjacent memory cells 20. The insulating film 31 allows a gap 29 (first gap) to be interposed between the side surfaces of the adjacent memory cells. The gap 29 is surrounded with the insulating film 27, the insulating film 31, and the semiconductor layer 3. The gap 29 may also be represented as e.g. void or air gap.

Furthermore, between adjacent memory cells, the insulating film formed on the semiconductor layer 3 is removed to expose the semiconductor layer 3 to the gap 29. Alternatively, the thickness of the insulating film on the semiconductor layer 3 between adjacent memory cells may be made thinner than that of the insulating film 27.

The miniaturization of the memory cells 20 results in narrowing the spacing between the adjacent memory cells 20. This causes variation in the threshold of the memory cell transistor due to capacitive coupling between the adjacent memory cells. For instance, in a memory cell of the FG (floating gate) structure, the coupling ratio C_{R}=C_{IPD}/(C_{IPD}+C_{OX}) may be kept constant to avoid the increase of write voltage. Then, the film thickness of FG cannot be thinned in accordance with the reduction of cell size. Thus, if the distance between adjacent cells is narrowed, the capacitive coupling increases in inverse proportion to the spacing. Here, C_{OX} is the tunnel oxide film capacitance between FG and the semiconductor layer. C_{IPD} is the inter-poly dielectric film capacitance between FG and the control gate.

On the other hand, multilevel technology has advanced in order to increase information stored in one memory cell. In multilevel technology, different pieces of information are associated with a plurality of threshold levels of a memory cell transistor. This decreases the margin between the threshold levels. Thus, the threshold variation due to capacitive coupling with the adjacent cell may cause errors in read information.

Furthermore, if FG is made thick relative to cell size, the aspect ratio of the memory cell is increased. This may cause collapse of the memory cell 20 at the time of patterning. This limits the aspect ratio of the memory cell. As a result, the coupling ratio is difficult to maintain.

In contrast, in the embodiment, a gap 29 is provided between the adjacent memory cells 20 to reduce parasitic capacitance therebetween. Thus, the effective spacing between adjacent FG is widened. This suppresses capacitive coupling between adjacent cells, and enables design with larger coupling ratio.

Furthermore, between adjacent memory cells, the thickness of the insulating film provided on the semiconductor layer 3 is thinned. This can increase the air gap ratio and the coupling ratio. Here, the air gap ratio is the ratio of the volume of the gap 29 between the adjacent memory cell stacks versus the entire volume of space between the adjacent memory cell stacks, wherein the memory cell stack includes the memory cell 20 and the control gate 30 stacked thereon. By narrowing the spacing between the upper surface of the semiconductor layer 3 and the lower end of the gap 29, the air gap ratio can be increased. More preferably, the insulating film on the semiconductor layer 3 is removed to expose the surface to the gap 29.

Next, the structure of the nonvolatile memory device 100 according to this embodiment is further described with reference to FIGS. 1 to 3B.

As shown in FIG. 1, the nonvolatile memory device 100 further includes an insulating film 35 provided on the insulating film 31, an interlayer insulating film 37 provided thereon, and a bit line 41 provided on the interlayer insulating film 37. The bit line 41 is electrically connected to the semiconductor layer 3 through a drain contact 43 in the region (drain region) on the opposite side of the select gate 40 from the memory cell 20.

An insulating film 33 (third insulating film) is provided on the semiconductor layer 3 in the drain region. The drain contact 43 penetrates through the insulating film 33 from the upper surface of the interlayer insulating film 37, and is in contact with the semiconductor layer 3. For instance, the drain contact 43 is a metallic contact plug provided inside a contact hole penetrating through the interlayer insulating film 37, the insulating film 35, the insulating film 31, and the insulating film 33.

The nonvolatile memory device 100 includes a gap 69 between the memory cell 20 and the select gate 40, and a gap 39 (second gap) between the select gate 40 and the insulating film 33.

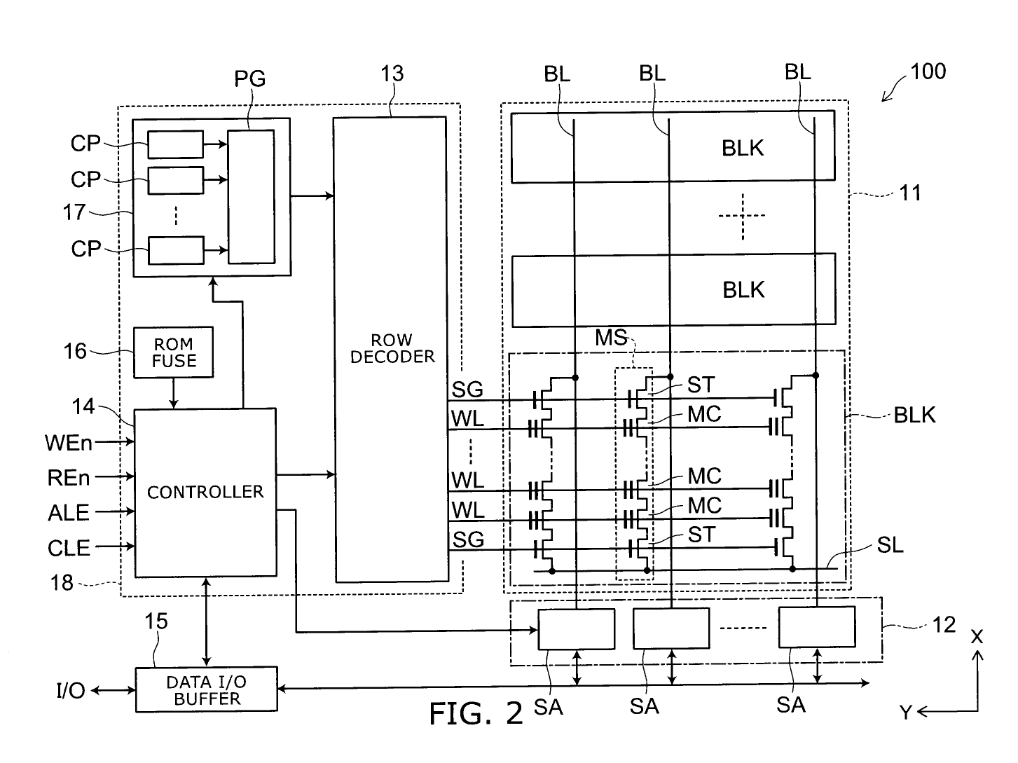

FIG. 2 is a block diagram showing the nonvolatile memory device 100. As shown in this figure, the nonvolatile memory device 100 includes a memory cell section 11, and peripheral circuits 12 and 18 for controlling the memory cell section 11.

The memory cell section 11 includes a plurality of bit lines BL extending in the X direction, and a plurality of word lines WL extending in the Y direction. For instance, the X direction and the Y direction are parallel to the upper surface of the silicon wafer, and orthogonal to each other. Furthermore, one memory block BLK is configured to have a plurality of, e.g. 64, word lines. The memory cell section 11 includes a plurality of, e.g. 1024, blocks BLK arranged in the X direction.

A pair of select gate lines SG is arranged on both sides of the memory block BLK. On the other hand, a memory cell string MS is placed immediately below the bit line BL. The word line WL includes a control gate 30. A memory cell MC is provided at the intersection of the memory cell string MS and the word line WL. A select transistor ST is provided at the intersection of the memory cell string MS and the select gate SG. One memory cell string MS includes 64 memory cells MC and two select transistors ST on both sides thereof.

A plurality of memory cell strings MS juxtaposed in the Y direction constitutes one memory block BLK. For each memory block, a source line SL extending in the Y direction is arranged so as to be shared by adjacent memory blocks BLK. In each memory cell string MS, the drain side of one select transistor ST is connected to the corresponding bit line BL, and the source side of the select transistor ST at the other end is connected to the source line SL.

The peripheral circuits 12 and 18 are arranged around the memory cell section 11. The peripheral circuit 12 includes a plurality of sense amplifiers SA, each connected to a bit line BL. The sense amplifier SA senses the potential of the bit line BL. The peripheral circuit 18 includes a row decoder 13. To the row decoder 13, the word lines WL and the select gate lines SG are connected. The row decoder 13 selects these wirings and applies voltage thereto.

The peripheral circuit 18 further includes a controller 14, a ROM fuse 16, and a voltage generating circuit 17. The controller 14 receives input signals such as write enable signal WEn, read enable signal REn, address latch enable signal ALE, and command latch enable signal CLE. Thus, the controller 14 controls the operation of the nonvolatile memory device 100. Specifically, the controller 14 controls such operations as write operation, read operation, and erase operation on data. The ROM fuse 16 stores fixed data. The controller 14 reads this fixed data as necessary.

The voltage generating circuit 17 includes a pulse generating circuit PG and a plurality of charge pumps CP. The charge pump CP is a circuit for generating a prescribed voltage. The generated voltage is outputted to the pulse generating circuit PG. In the pulse generating circuit PG, the voltage inputted from the charge pump CP is shaped into a pulse and outputted to the row decoder 13.

The nonvolatile memory device 100 further includes a data input/output buffer 15. The data input/output buffer 15 passes data between the sense amplifiers SA and external input/output terminals, and receives command data and address data.

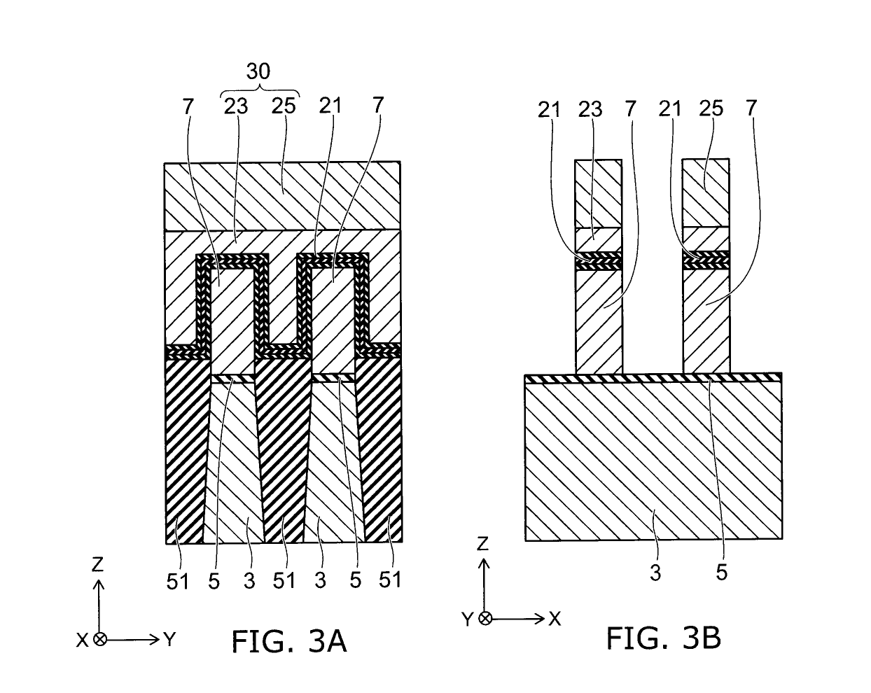

FIGS. 3A and 3B are schematic sectional views showing the memory cell 20 of the nonvolatile memory device 100 according to the first embodiment. FIG. 3A shows a cross section along the extending direction (Y direction) of the control gate 30 (word line WL). FIG. 3B shows a cross section along the extending direction (X direction) of the memory cell string 10.

The memory cell 20 has the FG structure. For instance, the memory cell 20 accumulates charge in the polysilicon layer provided on the semiconductor layer 3 via the tunnel insulating film 5.

As shown in FIG. 3A, the semiconductor layer 3 and the tunnel insulating film 5 constituting the memory cell 20 are processed into a stripe extending in the X direction. A plurality of memory cells 20 juxtaposed in the Y direction are insulated from each other by a device isolation insulating film 51. As shown in FIG. 3B, on the semiconductor layer 3, the polysilicon layer 7 is processed into a plurality of memory cells 20 arranged in the X direction. The IPD film 21 and the control gate 30 provided on the polysilicon layer 7 are processed into a stripe extending in the Y direction.

The semiconductor layer 3 is e.g. a p-type well region formed in a silicon wafer. The semiconductor layer 3 contains boron (B) in the concentration range from 1×10¹⁴ cm⁻³ to 1×10¹⁹ cm⁻³. Alternatively, the semiconductor layer 3 may be an SOI (silicon on insulator) layer.

The tunnel insulating film 5 is a silicon oxide film or silicon oxynitride film having a thickness of e.g. 3-15 nm. On the tunnel insulating film 5, a polysilicon layer 7 having a thickness of e.g. 30-200 nm is provided. The polysilicon layer 7 contains e.g. phosphorus (P) or arsenic (As) as n-type impurity in the concentration range from 1×10¹⁸ cm⁻³ to 1×10²¹ cm⁻³, and has conductivity. Furthermore, on the polysilicon layer 7, a control gate 30 is provided via an IPD film 21. The control gate 30 includes a polysilicon layer 23 and a silicide layer 25.

The polysilicon layer 7 is a charge accumulation layer. For instance, the polysilicon layer 7 is formed in a self-aligned manner with respect to the semiconductor layer 3 on the region where the device isolation insulating film 51 made of silicon oxide film is not formed. That is, the tunnel insulating film 5 and the polysilicon layer 7 are deposited on the semiconductor layer 3, and then etched to a depth reaching the semiconductor layer 3. Thus, the tunnel insulating film 5 and the polysilicon layer 7 are patterned like a stripe extending in the X direction. The etching depth of the semiconductor layer 3 is e.g. 0.05-0.5 μm. Then, the etched trench is filled with a device isolation insulating film 51 made of e.g. silicon oxide film. The tunnel insulating film 5 and the polysilicon layer 7 are formed on the semiconductor layer 3 free from step difference before the formation of the trench. Thus, the tunnel insulating film 5 and the polysilicon layer 7 are formed with high uniformity.

The tunnel insulating film 5 may be of a stacked structure such as SiN/SiO₂, SiN/SiO₂, SiO₂/SiO₂/SiN/SiO₂, SiO₂/high dielectric film/SiO₂, and high dielectric film/SiO₂. The device isolation insulating film 51 may be an insulating film including e.g. NSG (non-doped silicate glass), PSG (phosphorus silicon glass), BSG (boron silicon glass), PSZ (polysilazane), BPSG (boron phosphorus silicon glass), or HTO (high temperature oxide).

The IPD film 21 is a multilayer film or monolayer film including a high dielectric film such as silicon oxide film, silicon nitride film, hafnium aluminate film (HfAlO), alumina film (Al₂O₃), magnesium oxide film (MgO), strontium oxide film (SrO), barium oxide film (BaO), titanium oxide film (TiO₂), tantalum oxide film (Ta₂O₃), barium titanate film (BaTiO₃), barium zirconate film (BaZrO), zirconium oxide film (ZrO₂), hafnium oxide film (HfO₂), yttrium oxide film (Y₂O₃), zirconium silicate film (ZrSiO), hafnium silicate film (HfSiO), and lanthanum aluminate film (LaAlO). Alternatively, the IPD film 21 may be a film having a stacked structure such as SiN/high dielectric film/SiN, SiO₂/high dielectric film/SiO₂, and SiN/SiO₂/high dielectric film/SiO₂/SiN from the polysilicon layer 7 side. Further alternatively, the IPD film 21 may have a stacked structure of SiO₂/high dielectric film or SiN/high dielectric film from the polysilicon layer 7 side. For instance, the IPD film 21 is formed to a thickness in the range from 5 nm to 30 nm.

The control gate 30 can be made of e.g. polysilicon doped with phosphorus (P), arsenic (As), or boron (B) in the concentration range of 1×10¹⁷-1×10²¹ cm⁻³. Alternatively, the control gate 30 may be of a stacked structure of tungsten silicide (WSi) and polysilicon, or a stacked structure of at least one of NiSi, MoSi, TiSi, and CoSi, and polysilicon. Further alternatively, the control gate 30 may be of a stacked structure including metal oxide or metal (e.g., at least one of W, TaSiN, Ta, TiSi, TiN, Co, and Pt). The control gate 30 can be provided to a thickness of e.g. 10 nm to 500 nm.

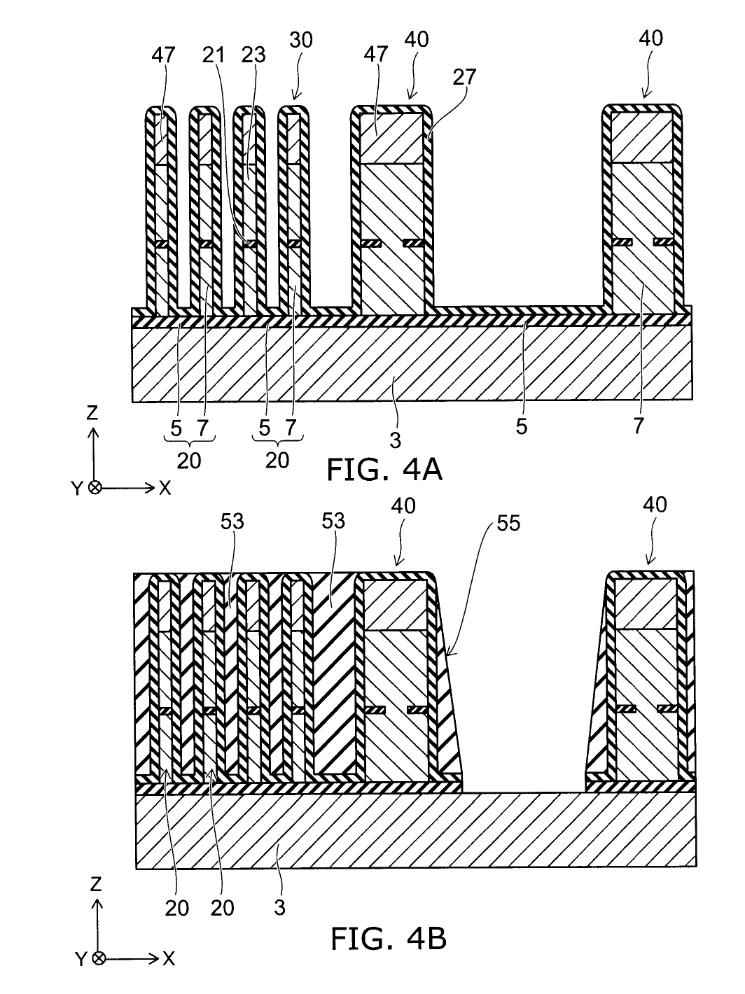

FIGS. 4A to 8 are schematic sectional views showing one example of a manufacturing process of the nonvolatile memory device 100 according to the first embodiment. FIGS. 4A to 8 show a cross section along the extending direction (X direction) of the memory cell string 10.

FIG. 4A shows a state in which the polysilicon layer 7, the IPD film 21, and the polysilicon layer 23 are separated in the X direction to form a memory cell 20, a control gate 30, and a select gate 40. On the polysilicon layer 23 is provided an insulating film 47 serving as a mask for etching the polysilicon layer 7, the IPD film 21, and the polysilicon layer 23.

On the semiconductor layer 3 extending in the X direction, a plurality of memory cells 20 and select gates 40 are juxtaposed with prescribed spacings. The control gate 30 provided on each memory cell 20 extends in the Y direction and is included in a word line WL. The select gate 40 also extends in the Y direction.

Then, an insulating film 27 is formed. The insulating film 27 covers the side surface crossing the X direction of the memory cell 20, the control gate 30, and the select gate 40. The insulating film 27 is e.g. a silicon oxide film. Furthermore, impurity is implanted into the semiconductor layer 3 between the adjacent memory cells 20, between the memory cell 20 and the select gate 40, and between the adjacent select gates 40 to form source/drain regions (not shown).

Next, as shown in FIG. 4B, the space between the adjacent memory cells 20, between the memory cell 20 and the select gate 40, and between the adjacent select gates 40 is filled with a sacrificial film 53. The sacrificial film 53 can be e.g. a silicon nitride film or organic film.

Then, the sacrificial film 53 between the adjacent select gates 40 is selectively removed by using e.g. RIE (reactive ion etching) technique to form a recess 55. On the side surface of the select gate 40, a sidewall film including the sacrificial film 53 and the insulating film 27 is left. In this etching process, the insulating film 27 and the tunnel insulating film 5 are removed to expose the semiconductor layer 3 at the bottom surface of the recess 55.

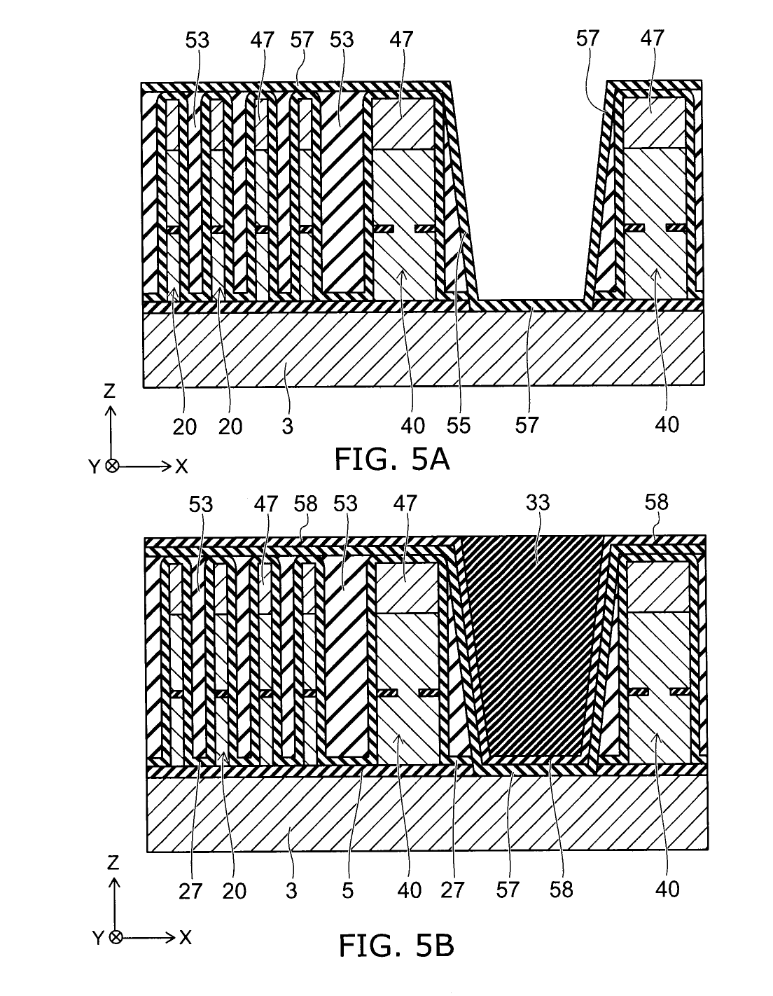

Next, as shown in FIG. 5A, an insulating film 57 is formed on the upper surface of the memory cell 20 and the select gate 40, the upper surface of the sacrificial film 53, and the inner surface of the recess 55. The insulating film 57 is e.g. a silicon oxide film or silicon oxynitride film.

Then, as shown in FIG. 5B, an insulating film 58 covering the insulating film 57 is formed, and an insulating film 33 filling the recess 55 is formed. The insulating film 33 is formed so as to cover e.g. the recess 55, the memory cell 20, and the select gate 40. Subsequently, by using CMP (chemical mechanical polishing) technique, the portion provided on the memory cell 20 and the select gate 40 is removed, and the insulating film 33 is left inside the recess 55. Here, the insulating film 58 functions as an etching stopper.

The insulating film 33 is e.g. a silicon oxide film having wet etching selectivity with respect to the sacrificial film 53. The insulating film 58 can be a silicon nitride film having etching selectivity with respect to the silicon oxide film.

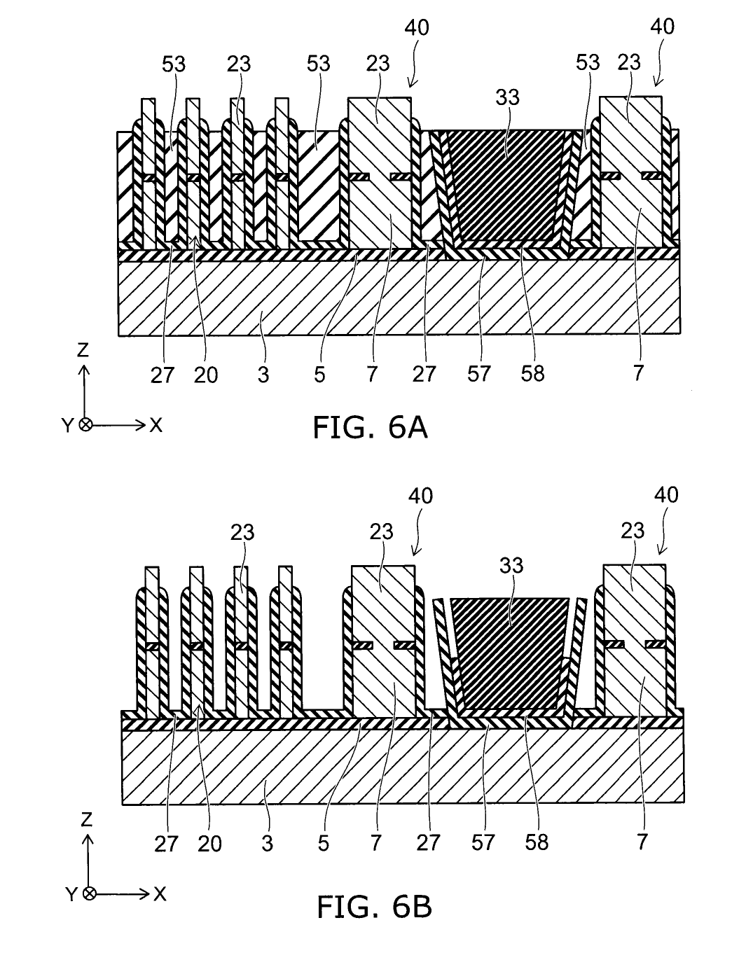

Next, as shown in FIG. 6A, the upper portion of the insulating film 58, the insulating film 57, and the sacrificial film 53 is removed by using RIE technique to expose the upper surface of the polysilicon layer 23.

Then, as shown in FIG. 6B, the sacrificial film 53 is removed by wet etching or CDE (chemical dry etching) technique. For instance, in the case where the sacrificial film 53 is a silicon nitride film, the portion including the silicon nitride film is removed except the insulating film 58 on the lower portion of the insulating film 33.

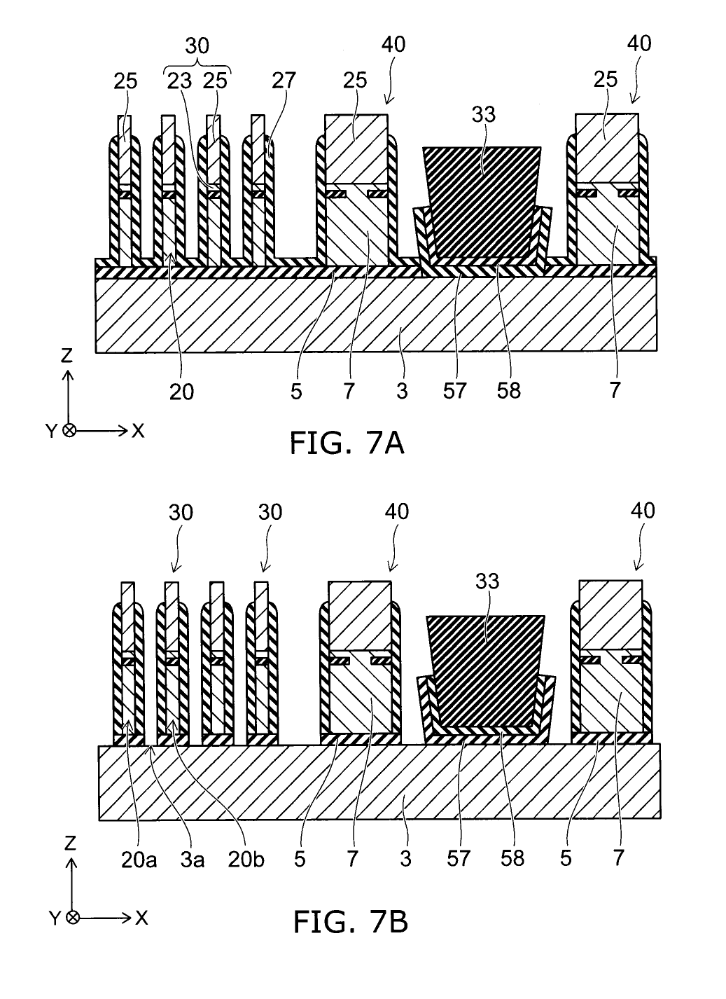

Next, as shown in FIG. 7A, the upper portion of the polysilicon layer 23 is silicidized. For instance, a metal layer including a transition metal of groups 4-11 such as nickel (Ni), titanium (Ti), cobalt (Co), platinum (Pt), palladium (Pd), tantalum (Ta), or molybdenum (Mo) is formed on the polysilicon layer 23. The metal layer is heat treated to silicidize the polysilicon layer 23. Subsequently, the metal layer is removed to form a silicide layer 25 on the polysilicon layer 23. In the example illustrated in this embodiment, the upper portion of the polysilicon layer 23 is silicidized. However, the entirety of the polysilicon layer 23 may be silicidized.

Next, as shown in FIG. 7B, the insulating film formed on the semiconductor layer 3 between the memory cells 20 is etched by using e.g. RIE technique. Here, by using anisotropic etching of RIE, etching of the insulating film 27 formed on the side surface of the memory cell 20 is suppressed, and etching of the insulating film formed on the semiconductor layer 3 is advanced. Thus, while leaving the insulating film 27 formed on the side surface of the memory cell 20 and the control gate 30, the insulating film formed on the semiconductor layer 3 can be selectively etched.

Preferably, the insulating film formed on the semiconductor layer 3 is completely removed to expose the semiconductor layer 3. However, a thin insulating film may be left. For instance, it is sufficient that the thickness of the insulating film on the semiconductor layer 3 is made thinner than the insulating film 27 formed on the side surface of the memory cell 20.

Here, as shown in FIG. 7B, the insulating film formed on the semiconductor layer 3 between the memory cell 20 and the select gate 40, and between the select gate 40 and the insulating film 33, is also simultaneously removed.

Next, on the control gate 30 and the select gate 40, a silicon oxide film as an insulating film 31 is formed by using e.g. plasma CVD (chemical vapor deposition) technique. In plasma CVD technique, when deposition is performed under a condition of poor embeddability, the film formation rate is slow in such a narrow space as between the adjacent memory cells 20. Accordingly, silicon oxide films are first formed above the control gate 30 and above the select gate 40, and then laterally connected to form a gap therebelow. Thus, gaps 29 and 69 are formed between the adjacent memory cells 20 and between the memory cell 20 and the select gate 40, respectively. Furthermore, a gap 39 is formed also between the select gate 40 and the insulating film 33. Here, preferably, no silicon oxide film is formed on the semiconductor layer 3. However, a silicon oxide film may be formed as thin as that deposited until the silicon oxide films are laterally connected above the select gate 40.

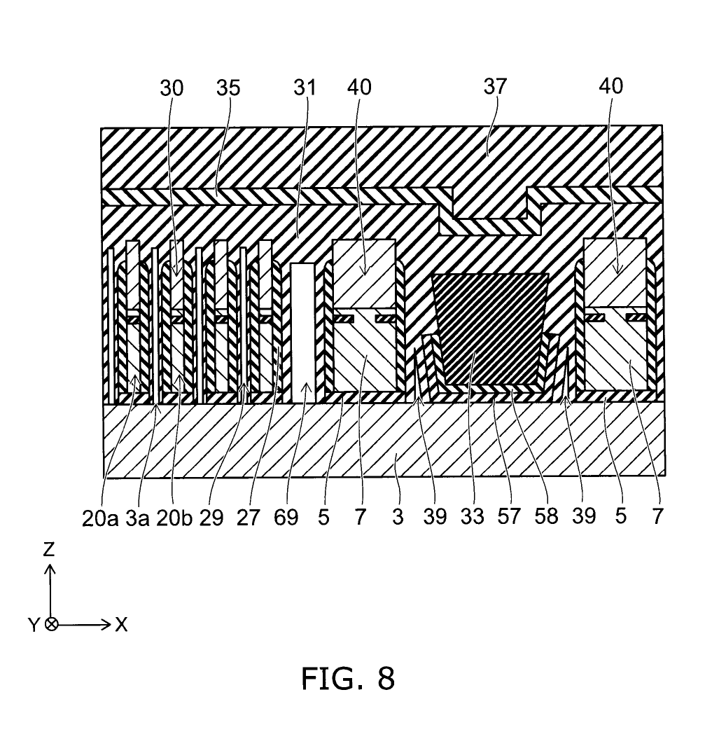

As shown in FIG. 8, an insulating film 35 is formed on the insulating film 31. Furthermore, an interlayer insulating film 37 is formed. Then, between the adjacent select gates 40, a contact hole is formed so as to penetrate from the upper surface of the interlayer insulating film 37 through the insulating film 35, the insulating film 31, the insulating film 33, and the insulating films 58, 57 to the semiconductor layer 3. Then, in the contact hole, a contact plug including tungsten (W) is formed by using e.g. CVD technique. Furthermore, a bit line 41 is formed on the upper surface of the interlayer insulating film 37. Thus, the memory cell section shown in FIG. 1 is completed.

As described above, in this embodiment, a gap 29 is provided between the adjacent memory cells 20 to reduce parasitic capacitance. Furthermore, the insulating film formed on the semiconductor layer 3 between the adjacent memory cells 20 is removed to increase the air gap ratio. This can increase the coupling ratio of the memory cell 20.

Thus, the height of the FG structure is lowered to prevent its collapse. This can improve the manufacturing yield. Furthermore, the coupling ratio can be increased to enhance the speed of writing and erasure. Furthermore, the semiconductor layer 3 between the adjacent memory cells 20 is exposed to the gap 29 to reduce traps occurring at the interface between the insulating film and the semiconductor layer. This results in suppressing accumulation of charge occurring at the interface between the insulating film and the semiconductor layer due to repetition of writing and erasure. Thus, current cutoff of the memory cell transistor can be prevented.

### Second Embodiment

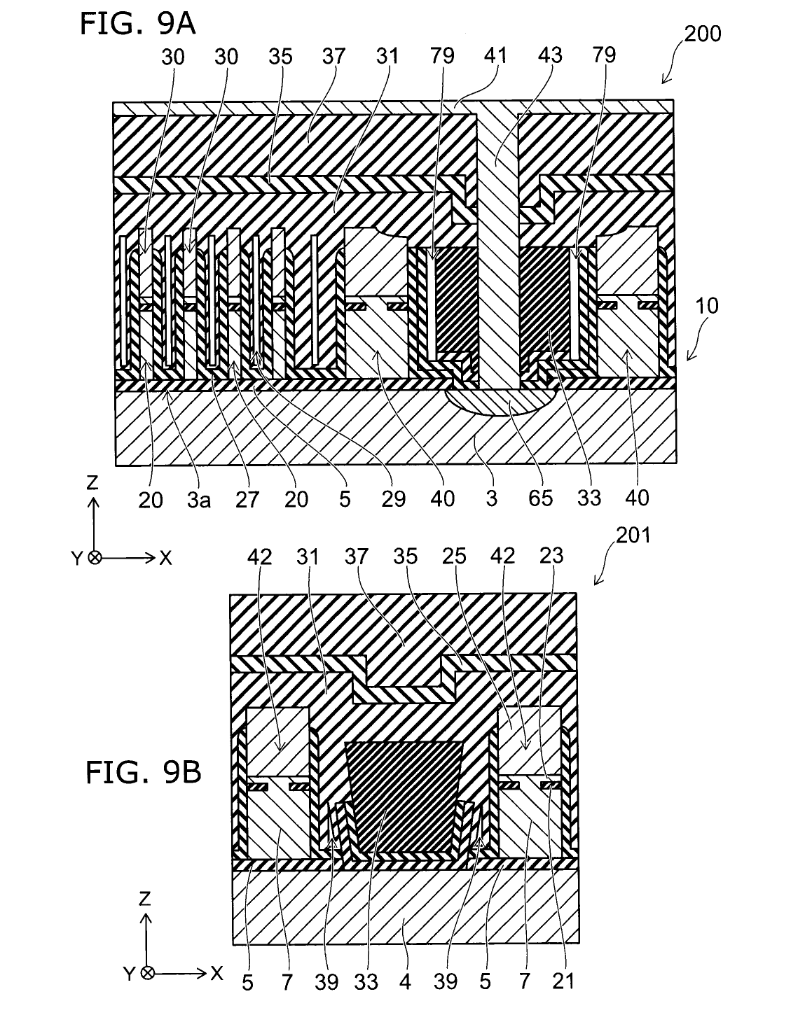

FIGS. 9A and 9B are schematic sectional views showing one example of a nonvolatile memory device 200 according to a second embodiment. FIG. 9A shows a cross section along the X direction of a memory cell string 10. FIG. 9B shows a cross section of a transistor 201 included in a peripheral circuit.

As shown in FIG. 9A, the nonvolatile memory device 200 is different from the nonvolatile memory device 100 shown in FIG. 1 in the structure in the drain region of the select gate 40. The configuration of the memory cell 20, the control gate 30, and the select gate 40 is the same as that of the nonvolatile memory device 100. A gap 29 is provided between the adjacent memory cells 20.

In this embodiment, a structure leaving an insulating film on the semiconductor layer 3 is described. However, as in the first embodiment, the insulating film on the semiconductor layer 3 may be removed.

The region (drain region) of the select gate 40 on the opposite side from the memory cell 20 is provided between two adjacent select gates 40. In the drain region, a drain contact 43 is provided. The drain contact 43 electrically connects the memory cell string 10 to the bit line 41 provided on the upper surface of the interlayer insulating film 37.

On the semiconductor layer 3 in the drain region, the insulating film 33, the insulating film 31, and the interlayer insulating film 37 are stacked. The drain contact 43 is provided inside a contact hole penetrating from the upper surface of the interlayer insulating film 37 through the insulating films to the semiconductor layer 3.

The drain contact 43 is a contact plug including e.g. tungsten (W). One end of the drain contact 43 is in contact with a contact region 65 provided in the semiconductor layer 3. The other end is in contact with the bit line 41.

The insulating film 33 in this embodiment is provided via a gap 79 on the side surface of the select gate 40 between the select gate 40 and the drain contact 43. The gap 79 is narrower than the spacing between two adjacent memory cells. As described later, a structure not including the gap 79 is also possible.

In the structure with the gap 29 interposed between the adjacent memory cells 20, a gap 79 is formed also between the select gate 40 and the insulating film 33 provided in the drain region of the select gate 40.

For instance, as shown in FIG. 1, if the gap 39 is formed with a wide width in the X direction, the contact hole may communicate with the gap 39 when forming the drain contact 43. More specifically, with the miniaturization of the memory cell section, the width in the X direction of the drain region is narrowed. Accordingly, the position of the contact hole may be displaced toward the select gate 40, and the contact hole may be connected to the gap 39. Then, when a metallic contact plug is formed inside the contact hole, a metal layer may be formed also inside the gap 39.

The gap 39 extends in the Y direction, and is formed across a plurality of memory cell strings 10. Thus, the metal layer formed inside the gap 39 causes a short circuit between memory cell strings 10.

In contrast, in this embodiment, the gap, if any, formed between the select gate 40 and the insulating film 33 is e.g. a narrow gap 79 along the side surface of the select gate 40. This can prevent the gap 79 from communicating with the contact hole of the drain contact 43. That is, the drain contact 43 and the gap 79 are spaced from each other. Furthermore, the gap 79 has an additional effect of reducing the leakage current between the select gate 40 and the drain contact 43.

Furthermore, as shown in FIG. 9B, in the transistor 201 included in the peripheral circuit, a gap 39 (fourth gap) is provided between the insulating film 33 (fourth insulating film) and the gate electrode 42 of the transistor. More specifically, the transistor 201 is formed by the same process as the memory cell 20 and the select gate 40. The transistor 201 includes a tunnel insulating film 5 functioning as a gate insulating film, a polysilicon layer 7, an IPD film 21, a polysilicon layer 23, and a silicide layer 25. The polysilicon layer 7 and the polysilicon layer 23 are electrically connected through the opening provided in the IPD film 21 and function as a gate electrode 42. An insulating film 33 is provided between the adjacent gate electrodes 42. A gap 39 is formed between the gate electrode 42 and the insulating film 33. The insulating film 33 is provided on both sides of the gate electrode 42. Thus, the gap 39 is formed on both sides of the gate electrode 42.

Thus, the gap 39 formed on both sides of the gate electrode 42 relaxes the fringe electric field and elongates the effective channel length. Accordingly, a transistor 201 with the short channel effect suppressed can be provided.

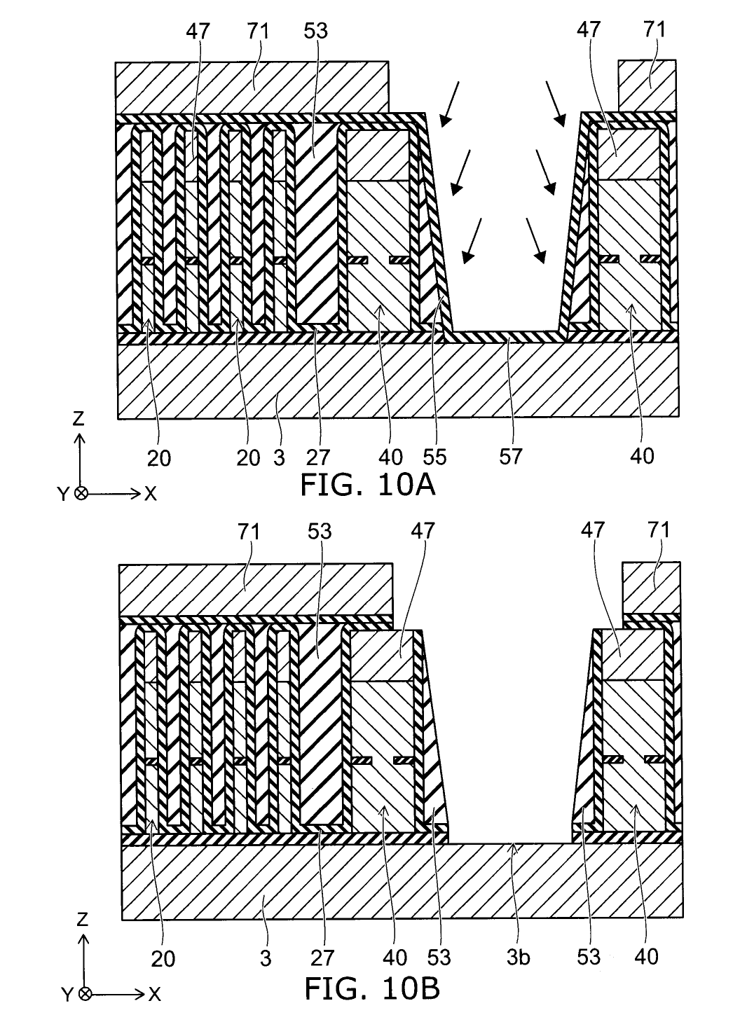

FIGS. 10A to 13B are schematic sectional views showing one example of a process for manufacturing the nonvolatile memory device 200 according to the second embodiment. FIGS. 10A to 13B show a cross section along the extending direction (X direction) of the memory cell string 10.

The manufacturing method according to this embodiment is the same as the manufacturing process of the first embodiment until the step shown in FIG. 5A. Thus, FIG. 10A shows a manufacturing process subsequent to FIG. 5A.

As shown in FIG. 10A, a resist mask 71 overlying the memory cell 20 and the select gate 40 is formed. The resist mask 71 includes an opening between the adjacent select gates 40. In this embodiment, for instance, impurity can be ion implanted through the opening of the resist mask 71 to adjust the threshold voltage of the select transistor formed between the select gate 40 and the semiconductor layer 3.

Next, as shown in FIG. 10B, the resist mask 71 is used as a mask to selectively remove the insulating film 57 by e.g. RIE technique or wet etching. Here, part of the insulating film 27 provided on the upper surface of the select gate 40 is also removed. Thus, part of the insulating film 47 is exposed.

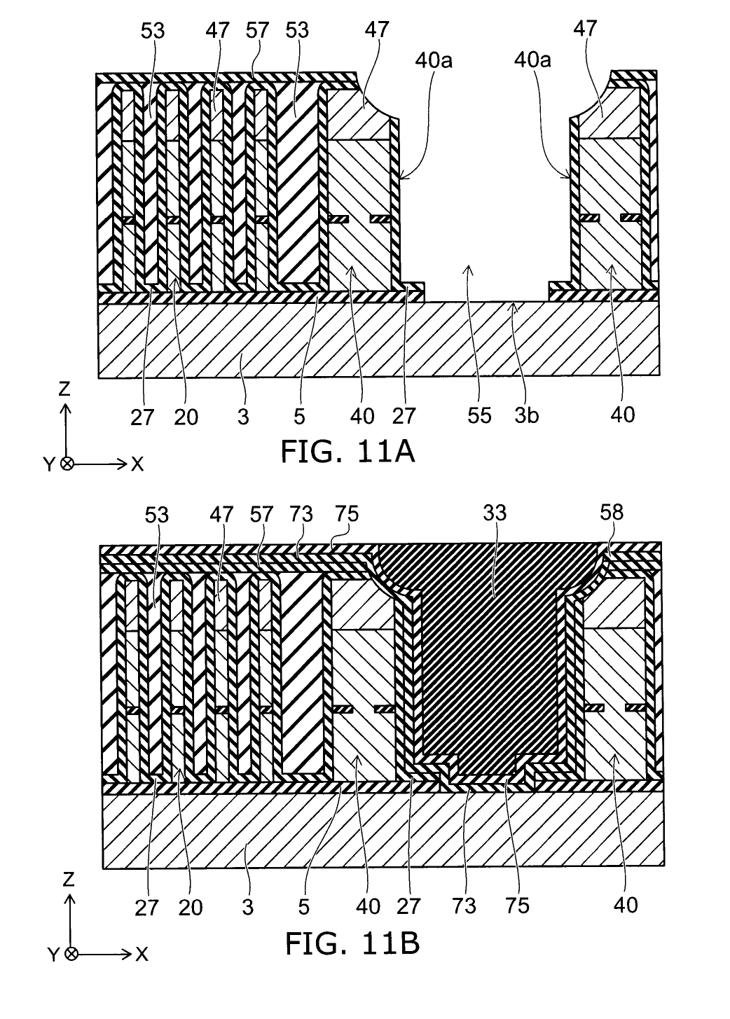

Next, as shown in FIG. 11A, the sacrificial film 53 remaining on the side surface 40a of the select gate 40 is removed by using wet etching or CDE technique. At this time, the sacrificial film 53 formed other than between the adjacent select gates 40 is not removed. However, the insulating film 47 formed on the select gate 40 is a silicon nitride film, and partly etched.

Next, as shown in FIG. 11B, an insulating film 73, and an insulating film 75 as an etching stopper are formed on the insulating film 57, the part of the insulating film and the side surface 40a of the select gate 40. Subsequently, an insulating film 33 filling between the select gates 40 is formed. The insulating film 33 is e.g. a silicon oxide film having wet etching selectivity with respect to the sacrificial film 53. For instance, the insulating film 75 is a silicon nitride film having etching selectivity with respect to the silicon oxide film.

The insulating film 33 is formed on the memory cell 20 and the select gate 40, and inside the recess 55. Then, planarization is performed using CMP technique. Thus, the insulating film 33 formed on the memory cell 20 and the select gate 40 is removed, leaving the portion formed inside the recess 55.

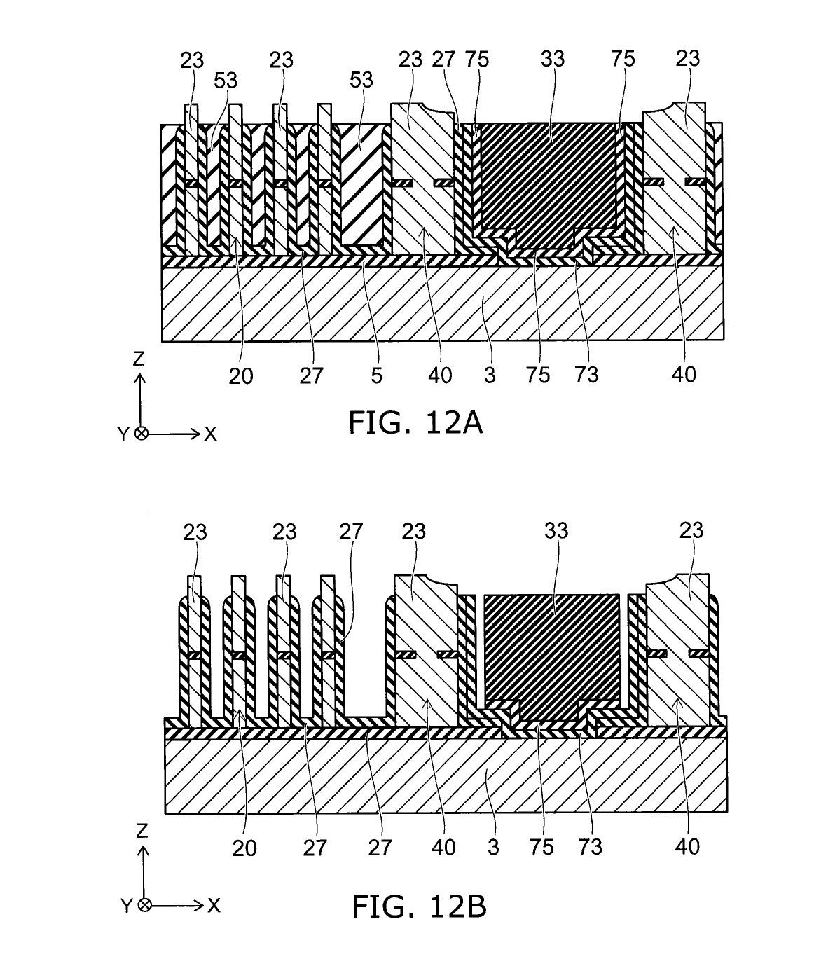

Next, as shown in FIG. 12A, the upper portion of the insulating film 75, the insulating film 73, and the sacrificial film 53 is removed by using RIE technique to expose the upper surface of the polysilicon layer 23. Then, a shape of the insulating film 47 may be transferred to the upper portion of the polysilicon layer 23. For example, since the insulating film 47 provided on the select gate 40 includes a thin portion, which is formed in the process shown in FIG. 11A, the polysilicon layer 23 provided on the select gate 40 may include the depressed portion corresponding to the thin portion of the insulating film 47.

Then, as shown in FIG. 12B, the sacrificial film 53 is removed using wet etching or CDE technique. For instance, in the case where the sacrificial film 53 is a silicon nitride film, the portion including the silicon nitride film is removed except the insulating film 75 on the lower portion of the insulating film 33.

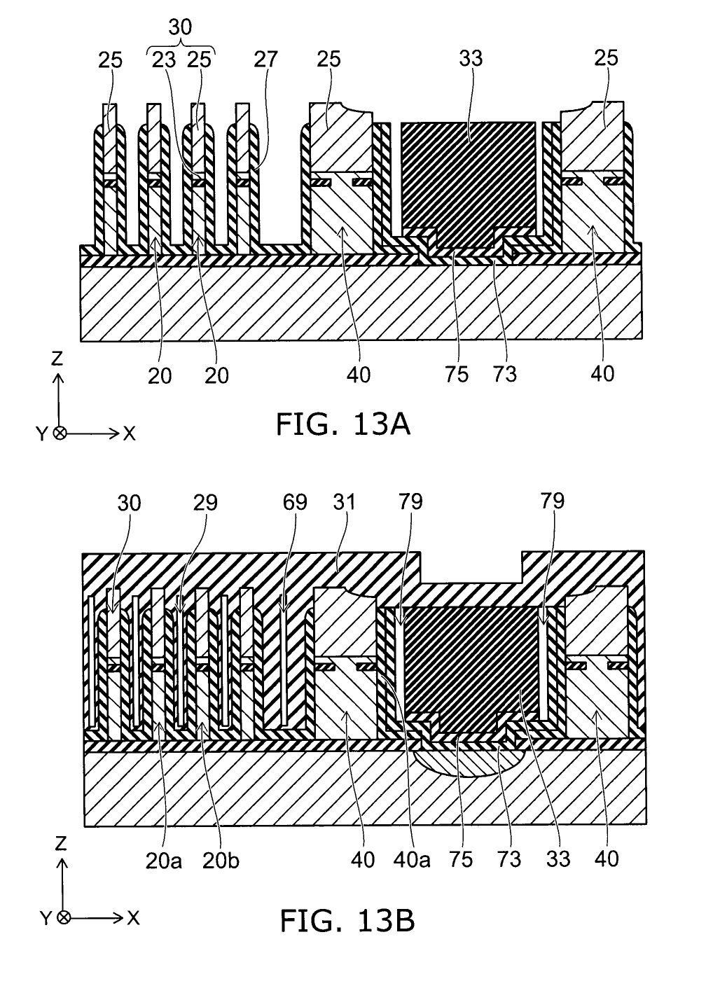

Next, as shown in FIG. 13A, the upper portion of the polysilicon layer 23 is silicidized to form a metal silicide 25 thereon. For instance, a metal layer including at least one of Ni, Ti, Co, Pt, Pd, Ta, and Mo is formed on the polysilicon layer 23. The metal layer is heat treated to silicidize the polysilicon layer 23.

Then, as shown in FIG. 13B, on the control gate 30, the select gate 40, and the insulating film 33, a silicon oxide film 31 is formed using e.g. plasma CVD (chemical vapor deposition) technique. Thus, gaps 29, 69, and 79 are formed between the adjacent memory cells 20, between the memory cell 20 and the select gate 40, and between the select gate 40 and the insulating film 33, respectively. The gap 79 formed between the select gate 40 and the insulating film 33 is a space resulting from the removal of the insulating film 75 formed on the side surface 40a of the select gate 40. Thus, the gap 79 is a narrow gap along the side surface 40a of the select gate 40. For instance, the film thickness of the insulating film 75 may be made thinner than the spacing between the adjacent memory cells 20 for forming a gap 79 narrower than the spacing.

Furthermore, an insulating film 35 is formed on the insulating film 31. An interlayer insulating film 37 is formed thereon. Then, between the adjacent select gates 40, a contact hole is formed so as to penetrate from the upper surface of the interlayer insulating film 37 through the insulating film 35, the insulating film 31, the insulating film 33, and the insulating films 75, 73 to the semiconductor layer 3. Then, in the contact hole, a contact plug including tungsten (W) is formed using e.g. CVD technique. Furthermore, a bit line 41 is formed on the upper surface of the interlayer insulating film 37. Thus, the memory cell section shown in FIG. 9A is completed.

For instance, in the above manufacturing process, if the insulating film 75 shown in FIG. 11B is an insulating film made of a material having etching selectivity with respect to the sacrificial film 53, the gap 79 is not formed. That is, a structure with no gap between the select gate 40 and the insulating film 33 can be realized.

In the portion provided with the peripheral circuit, no opening is provided in the resist mask 71 shown in FIGS. 10A and 10B. In the transistor of the peripheral circuit, the gate electrode 42 has the same structure as the select gate 40. The sacrificial film 53 is left on the side surface of the gate electrode 42, and a gap 39 is finally formed.

As described above, in this embodiment, the sacrificial film 53 formed on the side surface 40a of the select gate 40 is selectively removed. Thus, the width of the gap formed between the select gate 40 and the drain contact 43 can be narrowed. This can prevent short circuit between adjacent memory cell strings. Furthermore, the distance between adjacent select gates can be decreased. This can reduce the area of the memory cell section. That is, this can contribute to the increase of capacity or the reduction of manufacturing cost of the nonvolatile memory device.

Furthermore, a gap is formed near the gate electrode of the transistor used in the peripheral circuit. This can relax the fringe electric field and elongate the effective channel length. Accordingly, the short channel effect can be suppressed to improve the transistor characteristics.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a memory cell string including a semiconductor layer extending in a first direction and a plurality of memory cells disposed on the semiconductor layer in the first direction;
a control gate provided on each of the plurality of memory cells and extending in a second direction crossing the first direction;
a first insulating film covering each side surface crossing the first direction of the plurality of memory cells, and a side surface of the control gate; and
a second insulating film covering an upper portion of the control gate provided on each of two adjacent memory cells of the plurality of memory cells,
wherein a first air gap is disposed between the two adjacent memory cells and is surround by the first insulating film and the second insulating film, and the semiconductor layer is exposed by the first gap, or thickness of an insulating film between the first gap and the semiconductor layer is thinner than the first insulating film.

2. The device according to claim 1, further comprising:
a bit line electrically connected to the memory cell string through a drain contact;
a select gate disposed between the plurality of memory cells and the drain contact and extending in the second direction; and
a third insulating film disposed between the select gate and the drain contact,
wherein a second gap is disposed between the third insulating film and the select gate, the second gap having a width narrower than spacing between the two adjacent memory cells.

3. The device according to claim 2, wherein the drain contact and the second gap are spaced from each other.

4. The device according to claim 2, wherein the bit line is disposed on an interlayer insulating film covering the second insulating film and the third insulating film.

5. The device according to claim 3, wherein the drain contact penetrates through the interlayer insulating film and the third insulating film and is in contact with the semiconductor layer.

6. The device according to claim 1, wherein the first insulating film includes a silicon oxide film.

7. The device according to claim 1, wherein the second insulating film includes a silicon oxide film.

8. The device according to claim 4, wherein the drain contact is a contact plug including tungsten (W).

9. The device according to claim 1, wherein the memory cell includes a tunnel insulating film disposed on the semiconductor layer and a charge accumulation layer provided on the tunnel insulating film.

10. The device according to claim 1, further comprising:
a peripheral circuit configured to control writing and reading of information in the memory cell,
wherein the peripheral circuit includes a plurality of transistors and a fourth insulating film disposed between adjacent ones of the transistors, and
a fourth gap is disposed between a gate electrode of the transistor and the fourth insulating film.

11. A method for manufacturing a nonvolatile memory device, the nonvolatile memory device including:
a memory cell string including a semiconductor layer extending in a first direction and a plurality of memory cells disposed on the semiconductor layer in the first direction;
a control gate provided on each of the plurality of memory cells and extending in a second direction crossing the first direction; and
a select gate provided on both sides of the plurality of memory cells and extending in the second direction,
the method comprising:
forming a first insulating film covering a side surface crossing the first direction of the memory cell, and the semiconductor layer, between the memory cells;
etching the first insulating film formed on the semiconductor layer between the plurality of memory cells; and
forming a second insulating film covering an upper portion of the control gate so as to form a gap between side surfaces crossing the first direction of the plurality of memory cells.

12. The method according to claim 11, wherein the semiconductor layer is exposed inside the gap.

13. The method according to claim 11, wherein the first insulating film is etched so that an insulating film on the semiconductor layer is made thinner than the first insulating film on the side surface of the memory cell.

14. A nonvolatile memory device comprising:
a memory cell string including a semiconductor layer extending in a first direction and a plurality of memory cells disposed on the semiconductor layer in the first direction;
a control gate provided on each of the plurality of memory cells and extending in a second direction crossing the first direction;
a first insulating film covering each side surface crossing the first direction of the plurality of memory cells, and a side surface of the control gate;
a bit line electrically connected to the memory cell string through a drain contact;
a select gate disposed between the plurality of memory cells and the drain contact and extending in the second direction;
a second insulating film covering an upper portion of the control gate provided on each of two adjacent memory cells of the plurality of memory cells; and
a third insulating film provided between the select gate and the drain contact,
wherein a first gap is disposed between the two adjacent memory cells and is surround by the first insulating film and the second insulating film, and
a second gap is disposed between the select gate and the third insulating film, and the second gap has a narrower width than the first gap.

15. The device according to claim 14, wherein the drain contact and the second gap are spaced from each other.

16. The device according to claim 14, wherein the second gap is not disposed between the select gate and the third insulating film.
